(19) United States
(12) Patent Application Publication
(10) Pub. No.: US 2002/0068437 A1
(43) Pub. Date: Jun. 6, 2002

(54) Method of forming unlanded via

(76) Inventors: Ting-Chang Chang, Hsinchu (TW); Po-Tsun Liu, Hsinchu (TW)

Correspondence Address: CHARLES C.H. WU & ASSOCIATES, 7700 IRVINE CENTER DRIVE, Suite 710, Irvine, CA, 92618-3043, US

(21) Appl. No.: 09/732,770

(22) Filed: Dec. 5, 2000

(51) Int. Cl. H01L 21/44; H01L 21/4763

(52) U.S. Cl. 438/637; 438/618

(57) ABSTRACT

A method of forming an unlanded via. A substrate having a conductive wire thereon is provided. An etching stop spacer is formed on each sidewall of the conductive wire. An inter-metal dielectric layer is formed over the substrate. The inter-metal dielectric layer is patterned to form a via opening that exposes the conductive wire and then a metal plug that occupies the entire via hole is formed.

### BACKGROUND OF THE INVENTION

1. Field of Invention

The present invention relates to a method of forming multilevel interconnects for connecting semiconductor devices. More particularly, the present invention relates to a method of forming unlanded via to lower parasitic capacitance between conductive wires.

2. Description of Related Art

Following the miniaturization of semiconductor's feature line width, high operating speed, multi-functional, compact, low power consumption and low production cost ultra large-scale integrated (ULSI) circuits can be produced en-mass. Due to miniaturization and increase in integration, the number of interconnects necessary for connecting various semiconductor devices continues to increase. To resolve the interconnection problem, multilevel interconnect structures are now widely adopted in integrated circuit manufacturing. Since a plurality of metallic layers is formed in a multilevel interconnect structure, neighboring metallic layers must be separated by an insulating dielectric layer. Electrical connection between an upper and a lower metallic layer is achieved by forming a plug. The plug is formed by etching out a via hole in the dielectric layer followed by depositing a conductive material into the via hole. In semiconductor industry, the structure of having a plug inside a via hole is called a via.

To prevent misalignment of via hole pattern and consequent reduction in contact area between the via and the conductive wire, the conductive wire over the via hole position is patterned to form a larger width. This type of production method is often referred to as a landed via process.

A landed via demands more chip area so that the ultimate level of device integration will be constrained. A similar technique but with the width of the via identical to the width of the conductive line is now available. Since the via and the conductive wire have identical width, the via can rarely sit entirely on the conductive wire. This type of via is often referred to as an unlanded via. However, deviation often occurs when the unlanded via opening is patterned so that the inter-metal dielectric layer is frequently over-etched or even etched through and ending up in the substrate. Therefore, subsequently formed metallic plug inside the unlanded via opening may formed unwanted electrical contact leading to short-circuiting. Hence, device reliability will drop.

### SUMMARY OF THE INVENTION

Accordingly, one object of the present invention is to provide a method of forming an unlanded via. The method not only can prevent via offset and associated reliability problems that result from photolithographic and etching processes, but the method also can reduce parasitic capacitance between co-planar conductive wires. Hence, the unlanded via process can increase device integration and lower parasitic capacitance between conductive wires. Ultimately, a high-speed low-power ULSI chip can be produced.

To achieve these and other advantages and in accordance with the purpose of the invention, as embodied and broadly described herein, the invention provides a method of forming an unlanded via. First, a substrate having a conductive wire thereon is provided. An etching stop spacer is formed on each sidewall of the conductive wire. An inter-metal dielectric layer is formed over the substrate. The inter-metal dielectric layer is patterned to form a via opening that exposes the conductive wire. Metal is deposited to fill the via opening, thereby forming a metal plug.

In this invention, silicon carbide spacers are used as an etching stop layer. The silicon carbide spacer is capable of preventing any over-etching due to via hole misalignment. Because silicon carbide has a low dielectric constant, parasitic capacitance between co-planar conductive wire is also lowered.

It is to be understood that both the foregoing general description and the following detailed description are exemplary, and are intended to provide further explanation of the invention as claimed.

### BRIEF DESCRIPTION OF THE DRAWINGS

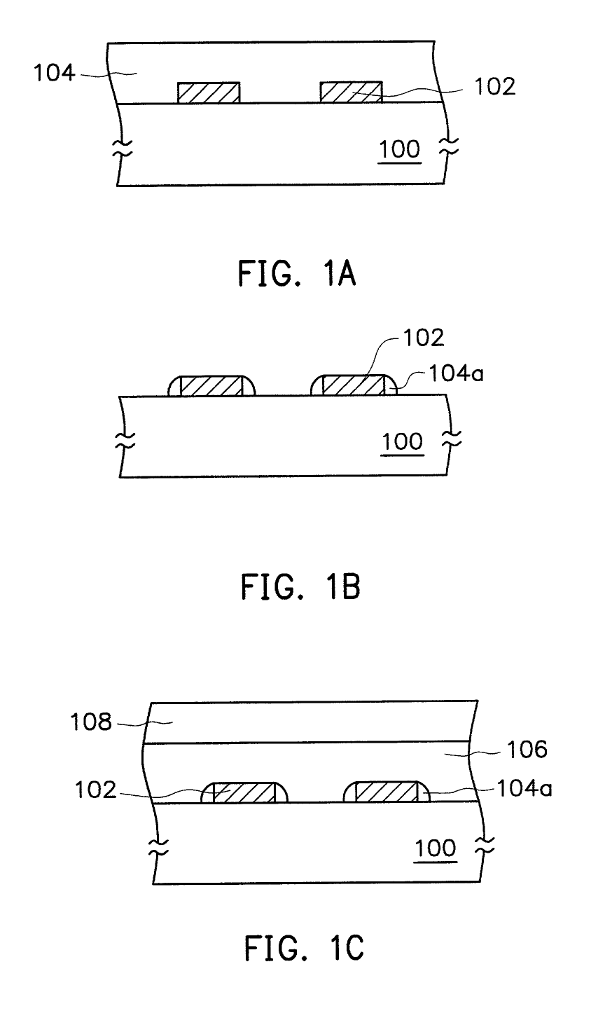

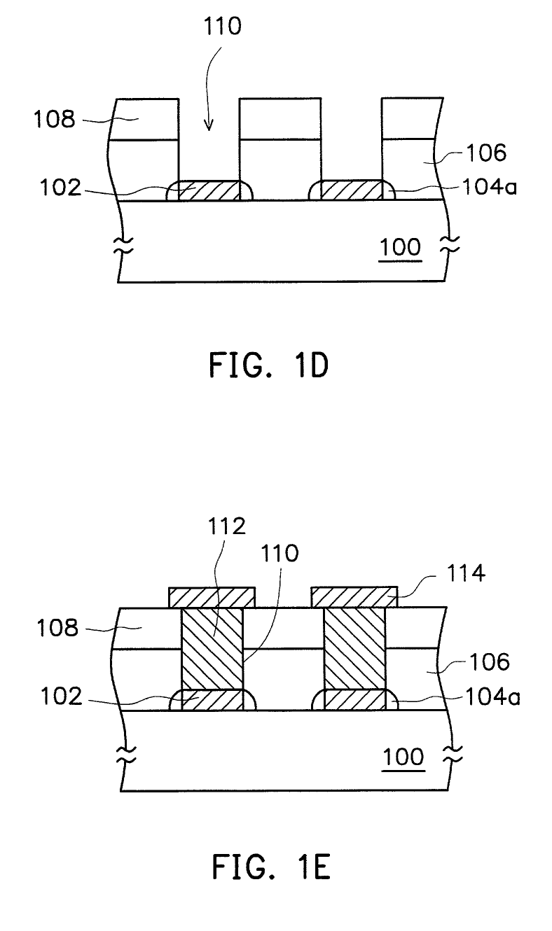

The accompanying drawings are included to provide a further understanding of the invention, and are incorporated in and constitute a part of this specification. The drawings illustrate embodiments of the invention and, together with the description, serve to explain the principles of the invention. In the drawings, FIGS. 1A through 1E are schematic cross-sectional views showing the progression of steps for producing an unlanded via and associated conductive wire in a metallic interconnect fabrication process according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIGS. 1A through 1E are schematic cross-sectional views showing the progression of steps for producing an unlanded via and associated conductive wire in a metallic interconnect fabrication process according to one preferred embodiment of this invention.

As shown in FIG. 1A, a substrate 100 (devices within the substrate are not fully drawn) having conductive wires 102 therein is provided. A dielectric layer 104 is formed over the substrate 100. The dielectric layer 104 is a low dielectric constant material, preferably silicon carbide such as BLOk developed by Applied Materials Company. BlOk not only has a dielectric constant (K) of about 4.5, but also has high etching selectivity relative to silicon dioxide (SiO₂).

As shown in FIG. 1B, a portion of the dielectric layer 104 is removed to form a spacer 104a on each sidewall of the conductive wire 103. The dielectric layer 104 is removed, for example, by anisotropic etching.

As shown in FIG. 1C, an inter-metal dielectric layer 106 with low dielectric constant is formed over the substrate 100. The inter-metal dielectric layer 106 has a large etching selectivity relative to the spacer 104a. The inter-metal dielectric layer 106 is preferably formed by spin-coating a low dielectric constant material (a dielectric constant smaller than 3.0) including hydrogen silsesquioxane (HSQ) or methylsilsesquioxane (MSQ).

An insulation layer 108 is formed over the inter-metal dielectric layer 106. The insulation layer 108 can be a silicon oxide layer formed, for example, by plasma-assisted chemical vapor deposition. The deposition is carried out using tetra-ethyl-ortho-silicate (TEOS) as reactive gas. The insulation layer 108 can prevent the aging of the low dielectric constant inter-metal dielectric layer during photolithographic and etching processes. In this invention, spacers 104a with low dielectric constant (dielectric constant of about 4.5) are formed on the sidewalls of the conductive wires 102. The spacers 104a have a dielectric constant much lower than conventional spacer material such as silicon nitride (Si₃N₄) (having a dielectric constant of about 7.9). Hence, the combination of low dielectric constant spacers 104a and low dielectric constant inter-metal dielectric layer 106 can lower parasitic capacitance and increase device performance considerably.

As shown in FIG. 1D, the insulation layer 108 and the inter-metal dielectric layer 106 are patterned to form via holes 110 that expose the conductive wire 102. Since the insulation layer 108 and the inter-metal dielectric layer 106 have etching rates much higher relative to the spacers 104a, the spacers 104a can serve as an etching stop layer. Consequently, even if misalignment occurs in photolithographic and etching processes, etching will stop on the spacers 104a without penetrating through the inter-metal dielectric layer 106, thereby forming abnormal contact when via plug is subsequently formed inside the via hole 110.

As shown in FIG. 1E, conductive material is deposited into the via holes 110 to form a via plug 112. The conductive material includes tungsten, for example. Finally, a patterned metallic layer 114 is formed over the insulation layer 108 and the via plug 112 to complete the fabrication of an unlanded via.

This invention provides a method of forming an unlanded via. Spacers 104a with low dielectric constant (about 4.5) are formed. In addition, etching selectivity between the inter-metal dielectric layer 106 and the spacers 104a is utilized. The spacers 104a can serve as an etching stop layer preventing the over-etching of the inter-metal dielectric layer 106 even if the via holes are misaligned. Hence, device reliability is improved.

Furthermore, the spacers 104a is made with a dielectric material having a dielectric constant much lower than conventional silicon nitride material. The low dielectric constant spacers 104 and the low dielectric constant (K<3.0) inter-metal dielectric layer 106 together is able to reduce parasitic capacitance between conductive wires considerably. In brief, the method not only can increase the level of device integration, but also can reduce parasitic capacitance. Ultimately, a high-speed low-power ULSI circuit chip is produced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming an unlanded via, comprising the steps of:
providing a substrate having a conductive wire therein;
forming an etching stop spacer on each sidewall of the conductive wire;
forming an inter-metal dielectric layer over the substrate;
patterning the inter-metal dielectric layer to form a via hole that exposes the conductive wire; and
forming a metal plug that occupies the entire via hole.

2. The method of claim 1, wherein material constituting the etching stop spacer includes silicon carbide.

3. The method of claim 1, wherein material constituting the inter-metal dielectric layer includes a spin-coated low dielectric constant compound.

4. The method of claim 3, wherein the spin-coated low dielectric constant compound includes hydrogen silsesquioxane (HSQ).

5. The method of claim 3, wherein the spin-coated low dielectric constant compound includes methylsilsesquioxane (MSQ).

6. The method of claim 1, wherein after the step of forming the inter-metal dielectric layer, further includes forming an insulation layer over the inter-metal dielectric layer.

7. The method of claim 6, wherein the step of forming the insulation layer includes performing a plasma-assisted chemical vapor deposition to form a silicon dioxide layer.

8. The method of claim 7, wherein the step of performing plasma-assisted chemical vapor deposition includes using tetra-ethyl-ortho-silicate (TEOS) as a gaseous reactant.

9. The method of claim 1, wherein the etching stop spacers and the inter-metal dielectric layer has different etching rates.

10. The method of claim 1, wherein the step of forming the via hole includes dry etching.

11. The method of claim 1, wherein material constituting the metal plug includes tungsten.

12. A method of forming an unlanded via, comprising the steps of:
providing a substrate having a conductive wire therein;
forming silicon carbide spacers on the sidewalls of the conductive wire;
forming a silsesquioxane layer over the substrate;
forming an insulation layer over the silsesquioxane layer;
patterning the insulation layer and the silsesquioxane layer to form a via hole that exposes the conductive wire; and
forming a metal plug that occupies the entire via hole.

13. The method of claim 12, wherein material constituting the silsesquioxane layer includes hydrogen silsesquioxane (HSQ).

14. The method of claim 12, wherein material constituting the silsesquioxane layer includes methylsilsesquioxane (MSQ).

15. The method of claim 12, wherein the step of forming the insulation layer includes performing a plasma-assisted chemical vapor deposition to form a silicon dioxide layer.

16. The method of claim 15, wherein the step of performing plasma-assisted chemical vapor deposition includes using tetra-ethyl-ortho-silicate (TEOS) as a gaseous reactant.

17. The method of claim 12, wherein the silicon carbide spacers and the silsesquioxane layer has different etching rates.

18. The method of claim 12, wherein the step of forming the via hole includes dry etching.

19. The method of claim 12, wherein material constituting the metal plug includes tungsten.
